(19) United States
(12) Patent Application Publication
(10) Pub. No.: US 2014/0004381 A1
(43) Pub. Date: Jan. 2, 2014

(54) ENHANCED MATERIALS AND INTERFACIAL PERFORMANCE VIA INFILTRATION

(71) Applicants: Jeffrey W. ELAM, Elmhurst, IL (US); Angel Yanguas-Gil, Naperville, IL (US)

(72) Inventors: Jeffrey W. ELAM, Elmhurst, IL (US); Angel Yanguas-Gil, Naperville, IL (US)

(21) Appl. No.: 13/536,545

(22) Filed: Jun. 28, 2012

(51) Int. Cl. B05D 1/36; B32B 9/00; B05D 5/00; C23C 16/44; B05D 5/06

(52) U.S. Cl. 428/688; 427/402; 427/248.1; 427/162; 427/256; 427/356

(57) ABSTRACT

An article and method of manufacture of a composite material. The method includes providing a starting scaffold with interfacial porosity, performing an infiltration step to fill the porosity and form a bond to the scaffold with an interface layer and forming an overlayer integrally coupled to the interface layer.

### STATEMENT OF GOVERNMENT INTEREST

The U.S. Government has rights in this invention pursuant to Contract No. W-31-109-ENG-38 between the U.S. Government and the University of Chicago and/or pursuant to DE-AC-02-06 CH11357 between the U.S. Government and the UChicago Argonne, LLC representing Argonne National Laboratory.

### FIELD OF THE INVENTION

This invention relates to articles of manufacture and methods for producing enhanced materials and improved interfacial structure performance via infiltration of materials into the basic material platform or scaffold. More particularly the articles and method relate to creating improved material properties and better interfaces between materials prepared by steps of low cost manufacturing methods for a scaffold followed by infiltration of a material. Such infiltration is accomplished, for example, by atomic layer deposition to promote interconnection to reduce porosity and to enable interface and surface engineering functions to be performed to provide advantageous materials.

### BACKGROUND OF THE INVENTION

A substantial need exists for rapid, low-cost production of various electronic components and devices, such as photovoltaic devices, light emitting diodes (“LEDs” hereinafter), and other photo-optical applications such as transparent conducting oxide (“TCO” hereinafter) based devices and even optical windows and displays. Current solution processing methods do enable cheap cost production casting of films using particles or inks of a desired composition. However, in order to achieve desired properties, an additional sintering process at high temperatures is required. Such multi-step, energy demanding steps are time consuming and very costly. Further, current best methods of manufacture are directed to roll-to-roll processing; and conventional methods are substantially incompatible. Therefore, there are many obstacles to the efficient manufacture of articles for a variety of applications which demand much improved performance and cost efficiency.

### SUMMARY OF THE INVENTION

A variety of low cost initial deposition methods can be used to provide a scaffold for subsequent infiltration. In one method a colloidal dispersion can be formed onto a substrate, such as by a doctor blade deposition of a thick film onto a glass or Si substrate. This step can be followed by an infiltration method, such ALD and other efficient infiltration methodologies, to selectively fill in porous volumes or form smooth and engineered surfaces for the resulting material to establish improved material and interfacial properties between the scaffold and the infiltrated material. Applications for such materials are for photovoltaic device systems, TCO, photo-optical devices, displays, smart windows, organic light emitting diodes (“OLED”) and tailored structures for electronic devices. Further, the method and articles of manufacture can be done at atmospheric pressure and low temperatures, which provide further efficiencies and cost reduction. One can use many convenient and low cost materials not otherwise usable in conventional methods, such as plastic substrates and other temperature sensitive components which would either not remain stable or would have substantially changed properties if processed by conventional high temperature methods.

These and other advantages and features of the invention, together with the organization and manner of operation thereof, will become apparent from the following detailed description when taken in conjunction with the accompanying drawings.

### BRIEF DESCRIPTION OF THE DRAWINGS

FIG. 1 illustrates a schematic flow diagram for producing a variety of films at different stages of processing;

FIG. 2A(1) and 2A(2) show a starting scaffold or thick film at different magnifications; FIG. 2B(1) shows a schematic of a scaffold film and FIG. 2B(2) shows an ALD infiltrated film; FIG. 2C shows a macrophoto of a scaffold of a nanoparticle dispersion in organic solvents deposited by one of doctor blade, screen print and drawdown production; FIG. 2D shows a micrograph of the film of FIG. 2C; FIG. 2E shows an micrograph of 500 nm thick ZnO layer with 40-100 nm of ZnO nanoparticles with a bonded consolidated morphology; FIG. 2F shows a cross section EDAX for a SnO₂ scaffold film and FIG. 2G shows a high magnification micrograph of three layers of the scaffold of FIG. 2F;

FIG. 3A shows a resulting film of a conducting layer; FIG. 3B shows a resulting film with interface engineering adding an interface film on the film of FIG. 3A; and FIG. 3C shows a resulting film with an added absorber layer on the film of FIG. 3B;

FIG. 4 shows sheet resistance of Al: ZnO ALD deposited on a ZnO scaffold film.

FIG. 5A shows sheet resistance versus ALD cycles for a variety of scaffolds; and FIG. 5B is a schematic showing lack of interfacial barriers and effect on carrier transport.

FIG. 6 shows resistivities for a variety of films obtained by ALD;

FIG. 7A shows resistivity versus T for two scaffolds, and FIG. 7B shows ZnO resistivity versus flat resistivity; and

FIG. 8 is a schematic of speed of ALD processing.

### DETAILED DESCRIPTION OF PREFERRED EMBODIMENTS

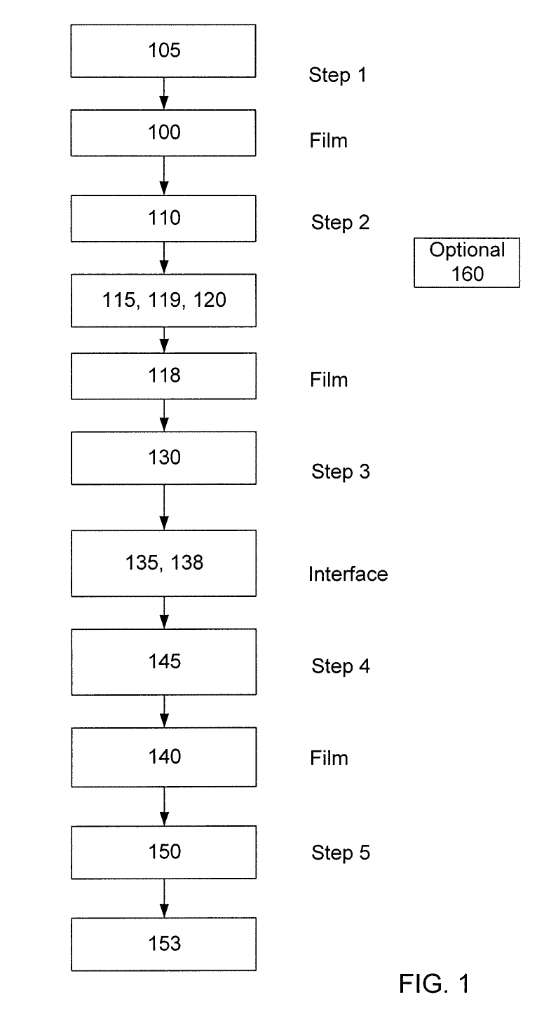

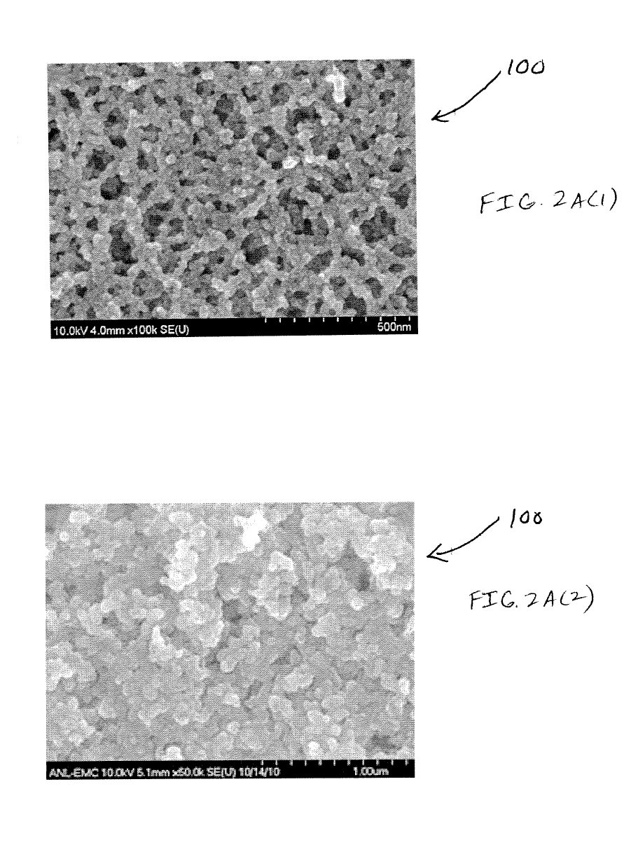

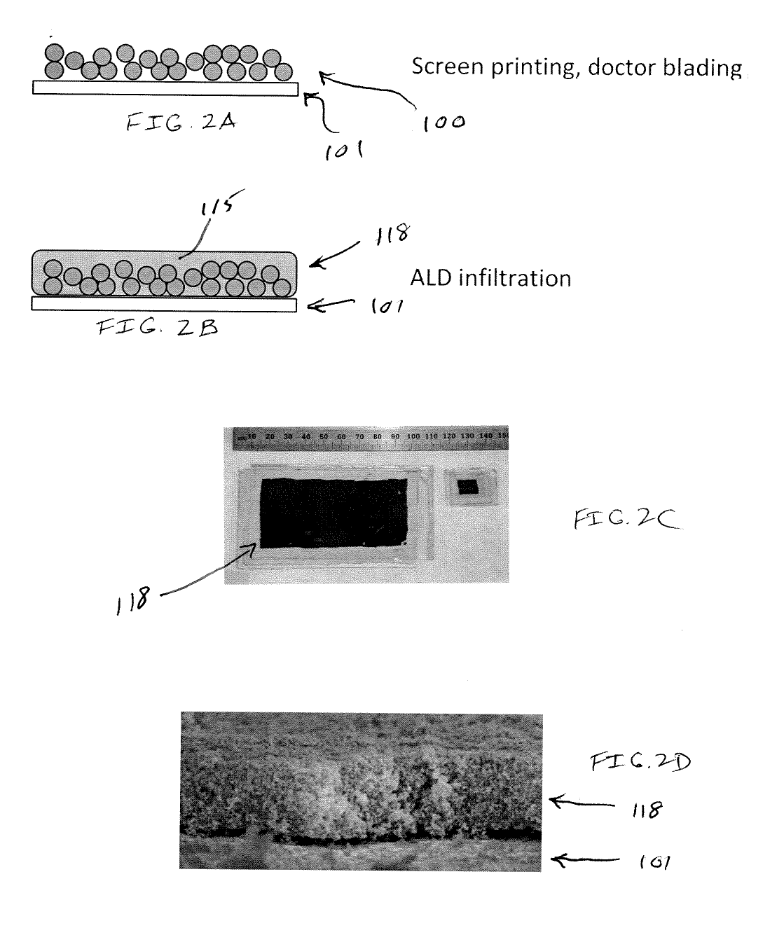

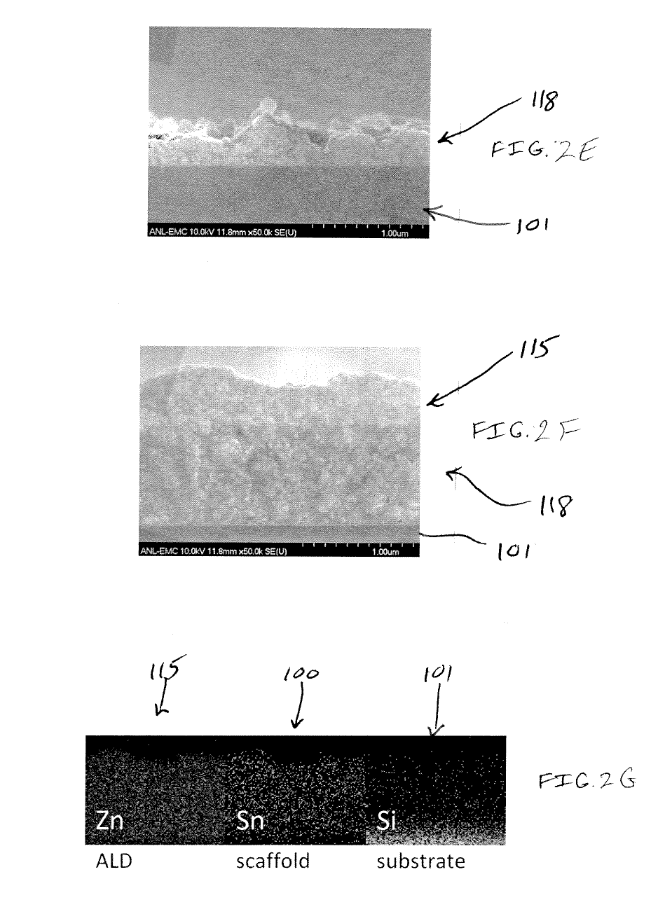

In order to fabricate thick films at low temperatures and under substantially atmospheric pressure and provide useful articles for a variety of commercial applications, a multi-step process has been developed. The method illustrated in FIG. 1 comprises the following preferred steps: A film 100 (see FIGS. 1 and FIGS. 2A(1)-2G) of the desired thickness is prepared by a method 105 based on a fast, low temperature methodology, including at least one of, for example, drawdown methods, doctor blade, screen and inkjet printing or liquid phase methods such as chemical bath deposition or colloidal synthesis. This film 100 includes structural units with desired properties, but the structural properties of the resulting material are poor due to bad interconnection of the structural units making up the film 100. The resulting porous materials of the film 100 are infiltrated using a low temperature process 110, including, but not limited to, ALD and chemical vapor deposition (“CVD” hereinafter), with a film most preferably of substantially the same nature and composition to that produced during the method 105. This treatments leads to better mechanical, electrical and optical properties. The infiltration acts to provide material 115 that binds the structural units of the film 100 deposited by the method 105 to form a composite thick film 118 (see FIGS. 2B-2G and 3A-3C) with the material 115 which fills the porosity of the film 100 and is integrally coupled to an overlayer 116. Much improved mechanical/electrical/optical properties are provided due to the improvement in the interconnection between the structural units; and for example, charge carriers and excitations can travel more easily through the network of the resulting composite 118. Improved microstructure also is obtained wherein the process or method 110 fills voids and can be used to tailor the surface roughness of the resulting material film 118. Better interfacial properties are also obtained. Additionally, as shown in FIGS. 3A-3C other components, such as the material 115 being an interface layer 120 and absorber layer 119 can provide a variety of useful and advantageous features otherwise not achievable. The interface 120 is designed using the method 110, and therefore becomes independent of the method used to fabricate the film 100 in the method 105. The method further enables better materials properties of the film 100 deposited during the method 105 because the film 118 deposited during the process step 110 controls the interfacial quality. Also, structural units with bigger sizes can be used, leading to higher crystalline domains than those typically obtained if conventional ink sizes are used. Finally, the process 110 can be used to mitigate any surface deterioration of the film 100, for instance due to exposure to ambient conditions. As an example, if the process 110 is carried out under reducing conditions, it can reverse any surface oxidation that may have occurred after the method 105.

By repetition of the methods 105 and 110 we can fabricate a stack of the thick films 118 using low temperature processes with improved properties with respect to the films 100 obtained using solely the method 105.

After the methods 105 and 110 are completed, the following steps can be used to fabricate forms of the improved the interfaces 120 (see FIG. 3B): (3) A thin film deposition method 130 (see FIG. 1), such as ALD or CVD, can be used to deposit material in order to control interfacial properties. The resulting film 135 is made of a different material compared to that obtained during the methods 105 and 110 to form another type of interfacial layer 138. A thin film 140 can be cast in a method step 145 using a fast, low temperature methodology, including, for example, drawdown methods, doctor blade, screen and inkjet printing or liquid phase methods, such as chemical bath deposition or colloidal synthesis. The composition of this film 140 is similar to that deposited during the method 130. Optionally, a method 150 similar to the method 110 can be added to adjust or improve the properties of the film 140. This can improve the contact of the film 140 fabricated during use of the method 145 with the interfacial layer 138 deposited during the method 130.

The advantage of the method 130 is that it improves the properties of the interfacial layer 138. In more detail, the method 130 ensures a good interfacial quality by reducing the probability of pinholes and the overall contact area between the two materials (the film 135 and the interfacial layer 138). In contrast, two films deposited using screen printing methods would have good contact only at the points in which the structural units of the two films meet. The method 130 also improves quality of the interface by the controlled deposition method used in the methods 110 and 130, thus eliminating the need for post-deposition treatments (for example, annealing, sulfurization, selenization processes) that otherwise would be needed to achieve good interfacial quality. Finally, another advantage of the combination of the methods 110 and 130 is that it effectively decouples the fabrication of the films from that of the interface 120/138, so that the methods 105 and 145 can be independently optimized without considering any interface quality requirement between the two materials. As an example, the methods 105 and 145 can be optimized to achieve higher throughputs or lower cost without sacrificing interfacial quality. In another example, the use of the methods 110 and 130 would also allow exposure to ambient conditions between methods 105 and 145 without negatively impacting the quality of the interface.

The proposed methods described above can be applied to a wide range of materials, including, but not limited to, metals and metallic alloys, oxides, sulfides, selenides, chalcogenides, nitrides, arsenides and phosphides and any combination of them. In particular, this method can be applied to low temperature processing in TCO applications and in thin film photovoltaics, including CIGS, CdTe, CZTS, and pyrite-based devices, to improve any or all of the layers/interfaces of the stack. In particular, this process could be used to improve the properties of photovoltaic devices printed on plastic substrates (thick or thin).

The methods described hereinbefore also can be applied to provide both continuous and patterned forms of the various films described before. For the latter form of the films, an etching step 160 (see FIG. 1) could be used at any point in the processing to remove one or more of the thin films in the unpatterned areas without the need of using masks or photoresists due to the high contrast in thickness between the screen-printed area and the bare surface.

The combination of methods 105 and 110 (and also methods 130, 145 and 150) allow a much faster and productive processing of thick films, particularly using the preferred deposition method of ALD while maintaining the same film quality then conventional methods. Such improvement is critical, for example, when a roll-to-roll process is used since it directly translates into a higher throughput.

The following non-limiting examples illustrate various aspects of the articles and methods of manufacture.

### Example I

A thick film 110 was obtained by the following procedures. In the method step 105 a doctor blade was used to deposit a 500 nm thick film of ZnO nanoparticles (size distribution ranging from 40 nm to 100 nm), Sb doped SnO₂ (40 nm diameter particles) and SnO₂ (40 nm particles) from the corresponding nanoparticle solutions in MeOH. In all cases the resulting films have poor mechanical and adhesion properties (they can literally be removed with finger pressure); and the sheet resistance is above the measuring range of the 4 point probe station (>2000 Ohm), despite the n-doping in the case of Sb doped SnO₂.

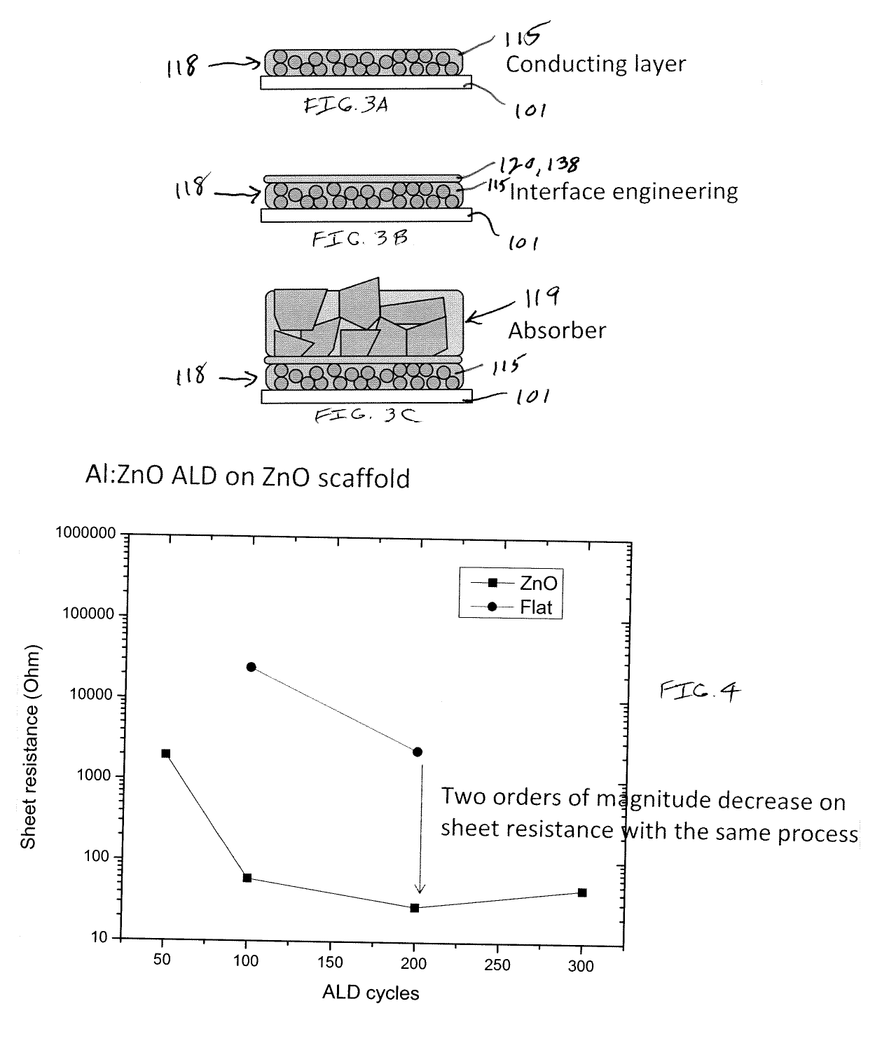

In the method step 110, a series of 100, 200 and 300 cycles of ZnO doped with 5% Al was deposited in a temperature range of 100-175 C. Diethyl zinc and trimethyl aluminum were used as precursors, and water was used as the oxygen source in both cases. Cross sectional EDAX measurements (see FIG. 2F) confirmed the complete infiltration the material 115 into the nanoparticle films 100, and in all cases the resulting composite 118 films presented good mechanical properties in terms of adhesion and scratching tests. In the case of a ZnO scaffold for the film 100, a dramatic decrease of the sheet resistance was obtained(see FIG. 4); and the corresponding resistivity was comparable with the best results obtained for Al:ZnO using Atomic Layer Deposition. Compared to Al:ZnO films grown on flat substrates, a two order of magnitude improvement in the sheet resistance for the film 118 was observed using the same processing conditions. Not only were the resistivity of the films 118 comparable to the best results reported in the literature of Al:ZnO films obtained by ALD, but a good correlation was observed between the resistivity of the Al:ZnO films 118 using only the method 110 and those combining the methods 104 and 110.

The results obtained confirm that: 1) substantially thicker films 118 can be obtained with the same material properties by combining the methods 105 and 110 compared to those obtained using the method 110 alone. 2) as seen in FIG. 4, a 100-fold improvement in resistivity was obtained by combining the methods 105 and 110 compared to the method 105 alone. 3) a 20-fold reduction in the processing time was achieved using the methods 105 and 110 with respect to the method 110 alone to achieve the same sheet resistance.

### Example II

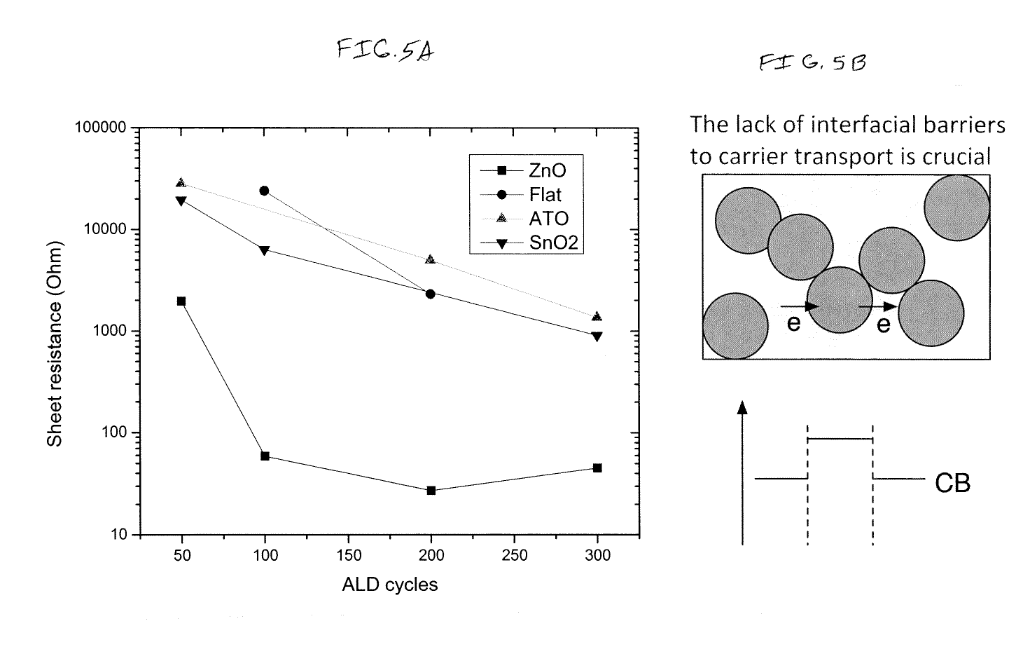

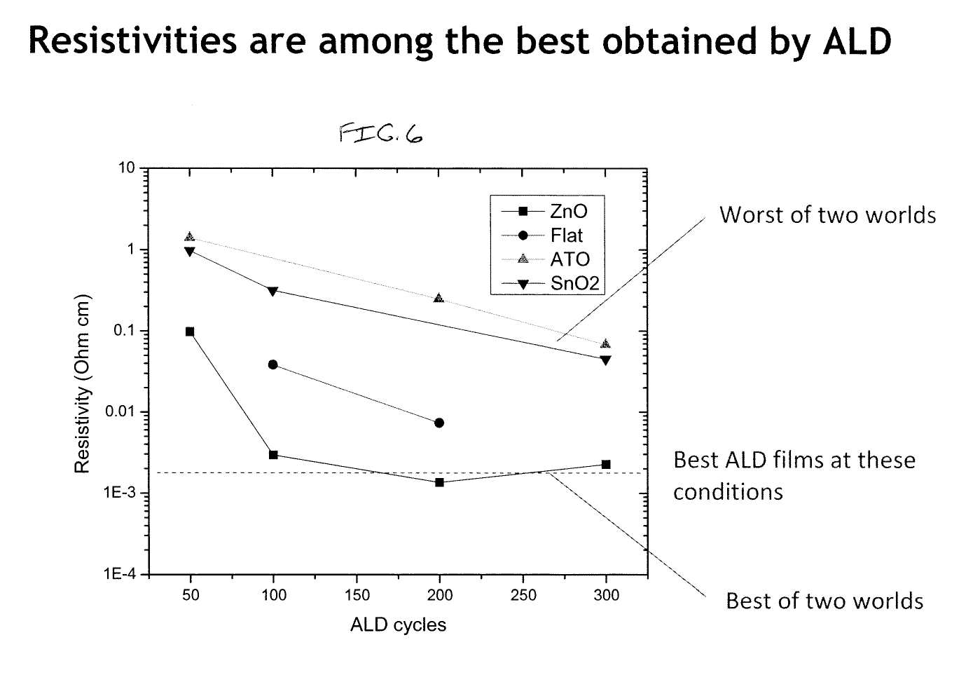

To emphasize the relevance of using similar materials for the methods 105 and 110, the performance properties of the films 118 that used dissimilar materials (SnO₂ and Sb:SnO₂ in method 105 and Al:ZnO during method 110) was significantly worse, for example, exhibiting higher resistivities than those of the ZnO films fabricated using the methods 105 and 110 and those obtained using the method 110 alone(see FIGS. 5A-6).

### Example III

For the methods 130 and 145, starting from the ZnO screen printing/Al:ZnO thin films, a TCO/TiO₂ interface for dye sensitized solar cells was fabricated by coating the ZnO with a 20 nm TiO₂ ALD layer from titanium tetrachloride and water at 200 C followed by the screen printing of a 2 micron thick TiO₂ film formed by 20 nm nanoparticles.

### Example IV

A disordered colloidal film was formed in the manner of the method 105 by use of intrinsic ZnO nanoparticles of a thickness of 5 microns which were doctor bladed onto glass and Si substrates. The resulting film 100 presented poor adhesion and mechanical properties and negligible conductivity.

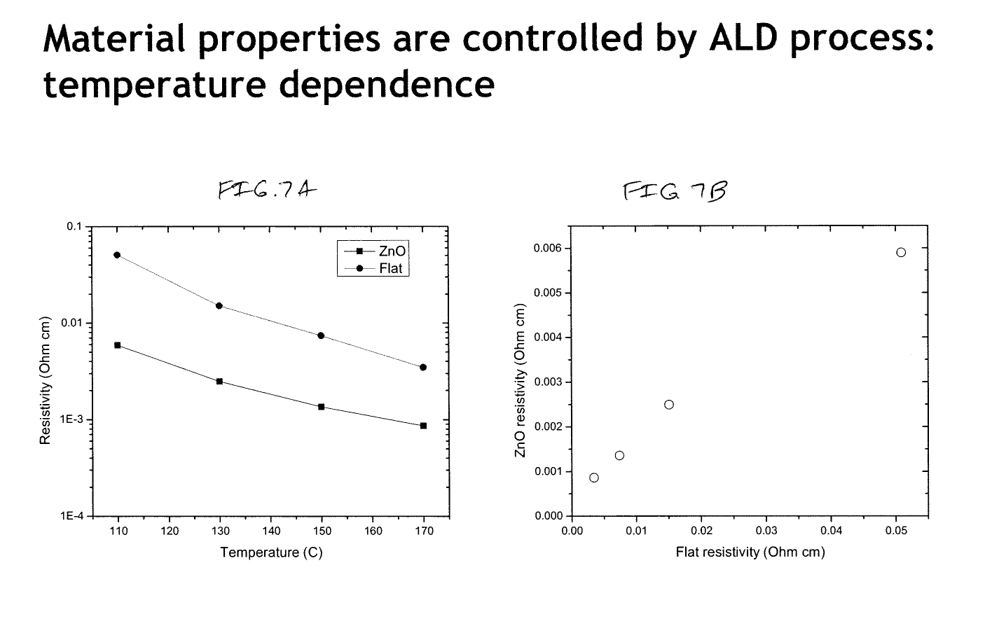

A process of performing 300 cycles of ALD formation of Al doped ZnO at 100 and 150 C was deposited onto the scaffold (the film 100). The resulting film 115 at 150 C yielded a sheet resistance of 5 ohms and a resistivity of 2 mOhms cm, comparable to the best Al-doped ZnO films obtained by ALD (see FIGS. 7A and 7B). The film 118 exhibited strong mechanical properties, with good adhesion. Due to the large particle size of the scaffold (the film 100 with 150 nm) light was strongly scattered by the resulting TCO layer 118.

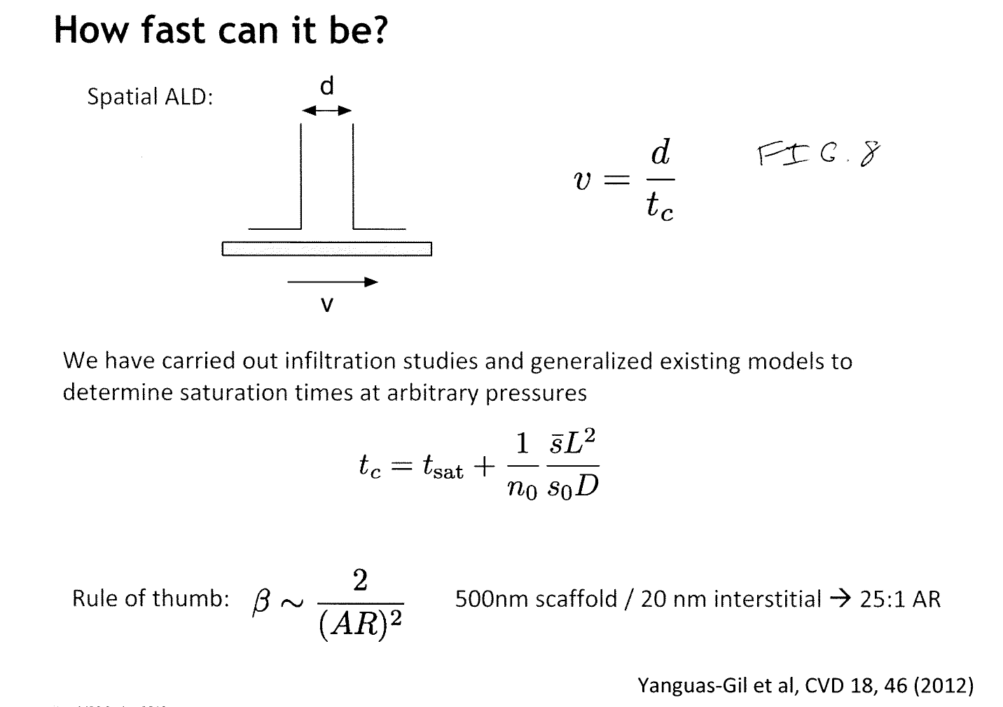

Deposition of TCO layers at atmospheric pressure is a long-standing issue in photovoltaic and the organic LED industry. The starting scaffold (the film 100) is deposited using conventional inexpensive methods. In a most preferred embodiment, ALD has been shown to perform well at atmospheric pressure and offers a way to overcome the limitations of existing procedures. It also avoids the need of carrying out a sintering process in order to better the mechanical properties and the cross linking of the colloidal films, something that it is crucial for devices based on plastic substrates. Moreover, the combination of ALD infiltrated into the film 100 opens a broad parameter space that can lead to tailored optical and electrical properties of TCO materials. For instance, by choosing the particle size the degree of scattering or haze can be controlled, and by using a conducting scaffold the TCO layer can be used to achieve a strong contrast on the optical properties (to control scattering) or to control the work function and the interfaces with the rest of the device stack. By controlling the degree of infiltration the contact surface area between the TCO and the next layer can be optimized (custom roughness). Finally, it reduces the ALD processing time required for the growth of extremely thick films. As noted in FIG. 8, the ALD method processing time can be characterized for commercial applications. For ALD processes characterized by a low reaction probability, the infiltration of porous substrates using the methods 110 and 130 does not substantially add processing time with respect to the deposition in flat surfaces. As a consequence of this, the viability of the process in a preferred embodiment, such as a roll-to-roll process, can be easily assessed using the relationship shown in FIG. 8 to determine the throughput of the methods 110 and 130.

The foregoing description of embodiments of the present invention has been presented for purposes of illustration and description. It is not intended to be exhaustive or to limit the present invention to the precise form disclosed, and modifications and variations are possible in light of the above teachings or may be acquired from practice of the present invention. The embodiments were chosen and described in order to explain the principles of the present invention and its practical application to enable one skilled in the art to utilize the present invention in various embodiments, and with various modifications, as are suited to the particular use contemplated.

1. A method of preparing a composite material, comprising the steps of,
providing a starting scaffold having interfacial porosity;
performing an infiltration step to fill the interfacial porosity of the scaffold with an interfacial layer; and
forming an overlayer whose matrix is integrally coupled to the interfacial layer.

2. The method as defined in claim 1 wherein the starting scaffold is formed by a step selected from the group of a draw-down method, a doctor blading step, a screen and inkjet method and a liquid phase method.

3. The method as defined in claim 2 wherein the liquid phase method comprises at least one of chemical bath deposition and colloidal synthesis.

4. The method as defined in claim 1 wherein the infiltration step comprises atomic layer deposition of an interface material.

5. The method as defined in claim 1 wherein composition of the interface material consists essentially of a composition of the starting scaffold.

6. The method as defined in claim 4 wherein composition of the interface material comprises a different composition than composition of the starting scaffold.

7. The method as defined in claim 1 wherein the infiltration step comprises CVD of an interface material.

8. The method as defined in claim 7 wherein composition of the interface material consists essentially of a composition of the starting scaffold.

9. The method as defined in claim 7 wherein composition of the interface material comprises a composition different than the starting scaffold.

10. The method as defined in claim 1 wherein the infiltration step includes selectively controlling surface roughness of the composite material.

11. The method as defined in claim 1 further including the step of providing an absorber layer for a selected optical application.

12. The method as defined in claim 1 wherein the infiltration step is carried out in a chemically reducing atmosphere to reverse surface oxidation of the composite material.

13. The method as defined in claim 1 further including the step of forming another type of interfacial layer in the composite material.

14. The method as defined in claim 1 further including a step of adjusting properties of the composite material to improve contact between the starting scaffold on the interfacial layer.

15. A method of preparing a composite material, comprising the steps of,
providing a starting scaffold having interfacial porosity;
performing an infiltration step by atomic layer deposition to fill the interfacial porosity of the scaffold with an interfacial layer; and
forming an overlayer by the atomic layer deposition and whose matrix is integrally coupled to the interfacial layer.

16. The method as defined in claim 15 wherein the starting scaffold is formed by a step selected from the group of a draw-down method, a doctor blading step, a screen and inkjet method and a liquid phase method.

17. The method as defined in claim 15 wherein composition of the interface material is selected from the group of a composition same as the scaffold and a composition different than the scaffold.

18. The method as defined in claim 15 wherein the infiltration step includes selectively controlling surface roughness of the composite material.

19. The method as defined in claim 15 further including the step of providing an absorber layer for a selected optical application.

20. A composite article of manufacture consisting of,
a starting scaffold having porosity;
an interface layer substantially filling the porosity of the starting scaffold; and
an overlayer integrally coupled to the interface layer.
